(19) United States
(12) Patent Application Publication
(10) Pub. No.: US 2026/0255528 A1
(43) Pub. Date: Aug. 27, 2026

(54) COMPUTING DEVICE FAN CONTROL

(71) Applicant: Microsoft Technology Licensing, LLC, Redmond, WA (US)

(72) Inventors: Gregory Allen NIELSEN, Kirkland, WA (US); Kristen Brooke SHIFLETT, Seattle, WA (US); Karan KACKER, Seattle, WA (US); Teng WU, Issaquah, WA (US); Yimeng LU, Bellevue, WA (US); Cho Yu CHONG, Kirkland, WA (US)

(73) Assignee: Microsoft Technology Licensing, LLC, Redmond, WA (US)

(21) Appl. No.: 19/062,459

(22) Filed: Feb. 25, 2025

(51) Int. Cl. H05K 7/20; G06F 1/20

(52) U.S. Cl. CPC H05K 7/20209; G06F 1/206

(57) ABSTRACT

A mobile computing device comprises a chassis, a fan inside the chassis, a temperature sensor, a processor, and memory storing instructions executable by the processor to determine a current temperature and a future temperature of the computing device. Operation of the fan is controlled based at least in part on the current temperature and the future temperature of the computing device.

### BACKGROUND

Some electronic devices, such as laptop and tablet computers, include one or more internal fans for cooling the device based on a current temperature of the device.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

As described in more detail below, computing devices and methods are configured to control operation of a fan of the computing device. In some examples, the computing device comprises a chassis, a fan inside the chassis, and a temperature sensor. A processor executes instructions stored in a memory of the computing device to determine a current temperature and a future temperature of the computing device. Operation of the fan is controlled based at least in part on the current temperature and the future temperature of the computing device.

As described in more detail below, some example configurations of the present disclosure utilize determinations of a future temperature of the computing device to delay starting operation of the computing device fan from a stopped condition, thereby reducing usage of the fan to correspondingly avoid noise produced by the fan and extend the useful life of the fan. Advantageously and in some examples described further below, the described configurations utilize determinations of a future temperature of the computing device to control fan operation in a manner that ensures the performance of the computing device processor is not undesirably impacted, such as by preemptively avoiding extreme thermal conditions and corresponding reductions in performance on the computing device processor(s). Additionally, in some examples the described configurations utilize determinations of a future temperature of the computing device to control fan operation in a manner that prevents undesirable oscillations of fan operation between stopped and operating conditions.

### BRIEF DESCRIPTION OF THE DRAWINGS

FIG. 1 depicts a mobile computing device according to examples of the present disclosure.

FIG. 2 shows a schematic representation of components of the computing device according to examples of the present disclosure.

FIG. 3 shows examples of fan speed plotted against chassis temperature of the computing device according to examples of the present disclosure.

FIGS. 4A-4C illustrate an example method of controlling operation of a computing device fan according to examples of the present disclosure.

FIG. 5 is a block diagram of an example computing system according to examples of the present disclosure.

### DETAILED DESCRIPTION

Some electronic devices, such as laptop and tablet computers, include one or more internal fans for cooling the device based on a current temperature of the device. In some examples excess or unnecessary fan operation can produce undesirable fan noise and reduce the useful life of the fan. In some examples, fan operation is started too late or at insufficient speeds, resulting in the computing device experiencing extreme thermal conditions and corresponding reductions in performance of the computing device processor(s). In other examples, a computing device fan can repeatedly oscillate between stopped and operating conditions, producing additional wear on the fan mechanism and creating an undesirable acoustic experience for a user.

Accordingly, the present disclosure describes computing devices and methods for controlling a computing device fan in manners that address one or more of the above drawbacks. As described further below, these computing devices and methods control fan operation in a manner that reduces usage of the fan to correspondingly avoid noise produced by the fan and extend the useful life of the fan. In some aspects the described configurations utilize determinations of a future temperature of the computing device to control fan operation in a manner that avoids or reduces performance degradations of the computing device processor, such as by preemptively avoiding extreme thermal conditions and corresponding reductions in performance of the computing device processor(s). For purposes of the present disclosure, the term “future temperature” means an estimated temperature at a future time. Additionally, the described configurations can utilize future temperature determinations to control fan operation in a manner that prevents undesirable oscillations of fan operation between stopped and operating conditions.

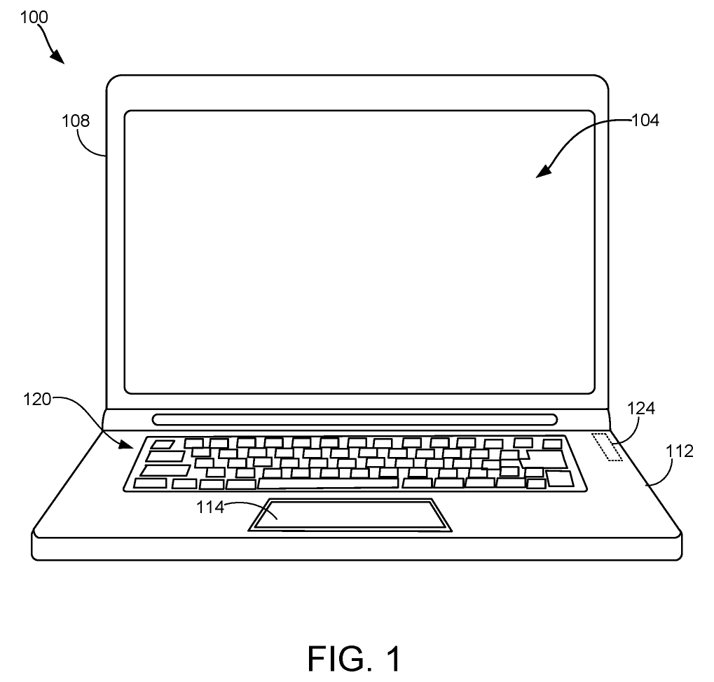

FIG. 1 illustrates an example computing device in the form of a laptop computer 100 that includes aspects of the present disclosure. In other examples a variety of other computing devices can be utilized with aspects of the present disclosure, including but not limited to tablet computing devices, wearable and other mobile computing devices, desktop computing devices, and any other type of computing device that utilizes one or more internal fans.

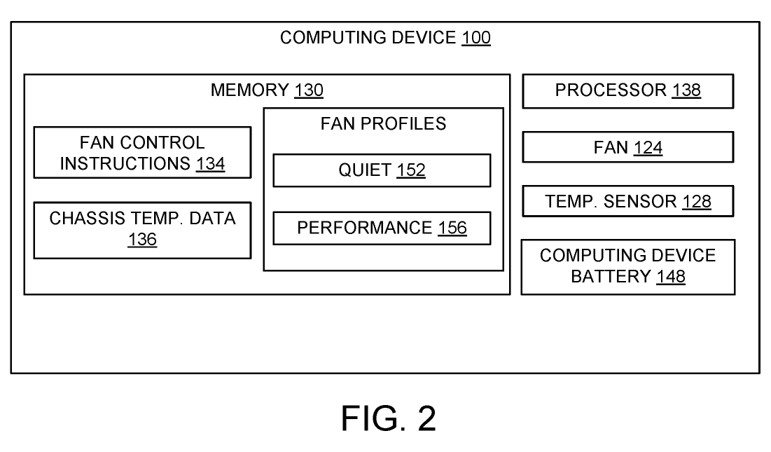

Computing device 100 includes a display 104 on a display substrate 108 that is rotatably coupled to a chassis 112. The chassis 112 includes a user input device in the form of trackpad 114 and a keyboard 120 mounted therein. With reference also to FIG. 2 and as described further below, inside chassis 112 computing device 100 includes a fan 124 that is selectively operated to reduce temperatures inside chassis 112. In some examples computing devices of the present disclosure can include two or more fans 124.

Computing device 100 also comprises a temperature sensor 128 configured to generate signals for determining a current temperature of the computing device. In some examples, signals from temperature sensor 128 are utilized to determine a temperature of the chassis 112 of computing device 100. In other examples, signals from temperature sensor 128 are utilized to determines a temperature of one or more other components of computing device 100, such as a processor. In some examples, computing devices of the present disclosure can include two or more temperature sensors 128.

As described further below, computing device 100 includes a memory 130 storing fan control instructions 134 that are executable by processor 138 to control operation of the fan 124 based at least in part on the current temperature of the computing device and a future temperature of the computing device (chassis temperature data 136). Additionally and in some examples, fan control instructions 134 can utilize additional data and parameters to control operation of fan 124. Such data can include power supply data (current, voltage, power, etc.), battery data (current, voltage, power, relative state of charge, etc.) from battery 148, and operating system data (gaming mode, high performance mode, power saving features, fan operational profiles, etc.).

As noted above, in some examples of electronic devices that utilize a current device temperature to operate an internal fan for cooling the device, excess or unnecessary fan operation can reduce the useful life of the fan and produce undesirable fan noise. These devices can experience extreme thermal conditions that trigger corresponding aggressive power reduction strategies that can negatively impact performance of the computing device processor(s) when fan operation is delayed or performed at insufficient speeds. In other examples, a computing device fan can repeatedly oscillate between stopped and operating conditions, producing additional wear on fan mechanisms and creating an undesirable acoustic experience for a user.

Accordingly, to address the above and other drawbacks, the present disclosure describes computing devices and methods for controlling operation of a computing device fan that are based at least in part on a determined future temperature of the computing device and the current temperature of the computing device. In some examples, fan control instructions 134 can include one or more machine learning algorithms, such as one or more transformer-based machine learning models, configured to determine a future temperature of the computing device 100. In some examples machine learning algorithms can utilize a time series forecasting model to utilize input data related to operation of the computing device to determine a future temperature of the computing device. Such input data can include, but is not limited to, power usage data, battery usage data, operating system mode data, and/or computing device temperature data. The machine learning algorithm(s) can be trained using this input data collected from computing device 100 over time and from other computing devices.

In other examples, fan control instructions 134 can include physics-based models and corresponding algorithms, such as a thermal network model (RC Model), that utilize input data related to operation of the computing device to determine a future temperature of the computing device 100.

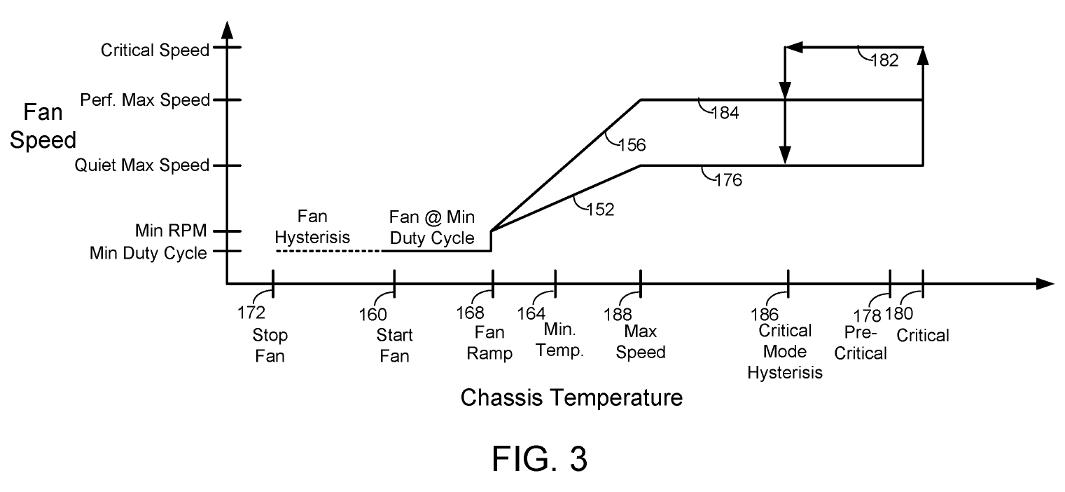

With reference now to FIG. 3, use case examples of controlling operation of a computing device fan are provided. In these examples and as described further below, a current temperature of the computing device and a future temperature of the computing device are determined, and operation of the fan is controlled based at least in part on the current temperature and the future temperature of the computing device.

FIG. 3 depicts along the X-axis a current temperature of chassis 112 of computing device 100, determined via signals received from temperature sensor 128, and along the Y-axis an operational speed of fan 124. In other examples, a current temperature of one or more other components of computing device 100, such as a processor, is alternatively or additionally utilized. With reference again to FIG. 2, in some examples a plurality of fan operation profiles is stored in memory 130, with each profile corresponding to different manners of controlling fan speed over a range of chassis temperatures. In the present example, a quiet fan operation profile 152 and a performance fan operation profile 156 are utilized, with each profile corresponding to different slopes of changing fan speed and different maximum fan speeds (see FIG. 3). In other examples, a single fan profile or three or more fan profiles can be utilized.

In some examples where the fan 124 is in a stopped condition (off), fan control instructions 134 are executed to determine that the current temperature of chassis 112 is equal to or above a start fan temperature threshold 160. The instructions also determine that a future temperature of the chassis 112 is below the start fan temperature threshold 160. Advantageously, based at least in part on determining that the future temperature of the chassis is below the start fan temperature threshold, fan control instructions refrain from starting operation of the fan 124 from the fan stopped condition.

In one use case example, the start fan temperature threshold 160 is 39 degrees Celsius (C), and at initial time X the current temperature of chassis 112 is 37 degrees C. Computing device 100 then executes a brief workload requiring significant power that causes processor 138 to rapidly generate heat. This heat is gradually transferred to chassis 112 and temperature sensor 128. At later time X+1 minute the current temperature of the chassis 112 is now at (or above) the start fan temperature threshold 160 of 39 degrees C, and the brief workload on processor 138 has ended, resulting in decreasing heat generated by the processor 138.

Also at time X+1 minute, fan control instructions determine that a future temperature of the chassis 112 at a predetermined future time, such as X+6 minutes (five minutes from the current time), will be 38 degrees C, which is below the start fan temperature threshold 160 of 39 degrees C. In other examples, the predetermined future time can be X+3 minutes, X+8 minutes, or any other suitable future predetermined time. Accordingly, and in one potential advantage of the present disclosure, based at least in part on determining that the temperature of chassis 112 at the predetermined future time will be below the start fan temperature threshold 160, fan control instructions refrain from starting operation of the fan 124 and allow the fan 124 to remain in the fan stopped condition. Advantageously, by refraining to operate the fan 124 in this manner, noise produced by fan operation is avoided and the useful life of the fan is extended.

In some examples, the current temperature of the chassis 112 is determined to be above the start fan temperature threshold 160 and also above a minimum temperature threshold 164 that is greater than the start fan temperature threshold 160. In one example where start fan temperature threshold 160 is 39 degrees C, minimum temperature threshold 164 can be 41.5 degrees C. In these examples, even when fan control instructions 134 determine that the future temperature of the chassis 112 at the predetermined future time will be below start fan temperature threshold 160, because the current temperature of the chassis 112 is above the minimum temperature threshold 164, fan control instructions start operation of the fan from the fan stopped condition to begin cooling chassis 112 and computing device 100 to advantageously protect against thermal events that could cause rapid increases in chassis 112 and computing device 100 temperatures that could be exacerbated in view of the chassis temperature reaching the minimum temperature threshold 164.

In some examples and with continued reference to FIG. 3, at an initial time X the current temperature of chassis 112 is determined to be 39 degrees C (equal to the start fan temperature threshold 160). Also at time X, fan control instructions 134 determine that a future temperature of the chassis 112 at the predetermined future time, such as X+5 minutes (five minutes from the current time), will be equal to or above the start fan temperature threshold 160. Accordingly and in these examples, based at least in part on determining that the future temperature of the chassis is equal to or above the start fan temperature threshold, fan control instructions 134 start operation of the fan from the fan stopped condition to advantageously begin cooling the chassis 112 and computing device 100.

In some examples, instead of starting the fan 124 from the fan stopped condition to initially operate at a predetermined minimum speed, such as 3000 RPM, until fan control instructions 134 cause a change in fan speed, fan control instructions initially start operation of the fan from the fan stopped condition at a slower, minimum duty cycle of the fan, such as 2000 RPM. Advantageously, in these examples initially operating the fan 124 at its minimum duty cycle instead of a faster minimum speed reduces chassis temperatures for normal, lower power loads, which correspondingly reduces a likelihood of the fan rapidly oscillating on/off between the stopped and operating conditions. Additionally, initially operating the fan 124 at its minimum duty cycle reduces the temperature gradient on the battery to correspondingly increase battery reliability, and in some examples operates the fan in an acoustically imperceptible manner to provide an improved user experience.

In some examples when fan 124 is operating at an initial speed, such as its minimum duty cycle speed, fan control instructions 134 determine that the chassis temperature is equal to or above a fan ramp temperature threshold 168. Based at least on determining that the chassis temperature is equal to or above the fan ramp temperature threshold 168, fan control instructions 134 increase a speed of the fan to a minimum fan speed that is greater than the minimum duty cycle speed of the fan at the minimum duty cycle. Advantageously and in these examples, when the chassis temperature is equal to or above the fan ramp temperature threshold 168, the speed of fan 124 is increased to provide greater cooling to the chassis 112.

In some examples when fan 124 is operating, fan control instructions 134 determine that the current chassis temperature is equal to or below a stop fan temperature threshold 172, such as 37 degrees C, and/or determine that the future temperature of the chassis is equal to or below the start fan temperature threshold 160, wherein the stop fan temperature threshold is less than the start fan temperature threshold. In these situations, based at least in part on determining that the current temperature is equal to or below the stop fan temperature threshold 172 and/or the future temperature is equal to or below the start fan temperature threshold 160, fan control instructions 134 cease operation of the fan 124 from the fan operating condition.

In one use case example where the current chassis temperature is above the stop fan temperature threshold 172 and fan control instructions 134 determine that the future temperature of the chassis is equal to or below the higher start fan temperature threshold 160, fan control instructions 134 cease operation of the fan 124 from the fan operating condition. Advantageously, in this manner fan control instructions 134 stop operation of the fan 124 more quickly when cooling of chassis 112 is predicted, thereby reducing utilization of the fan to correspondingly reduce power consumption, increase useful life of the fan, and potentially provide quieter operation of the computing device.

In some examples when fan 124 is operating, fan control instructions 134 determine that the current chassis temperature is below the stop fan temperature threshold 172 and that the future chassis temperature is equal to or above the stop fan temperature threshold. Based at least in part on determining that the future chassis temperature is equal to or above the stop fan temperature threshold, fan control instructions 134 refrain from ceasing operation of the fan from the fan operating condition.

In these examples, by determining that the future chassis temperature is equal to or above the stop fan temperature threshold 172, fan control instructions determine that the chassis temperature, though currently below the stop fan temperature threshold, will shortly increase above this threshold. Advantageously and in these examples, by continuing to operate the fan to provide cooling air flow, fan control instructions 134 avoid rapidly oscillating fan 124 on/off between the stopped and operating conditions, to correspondingly provide steady operation of the fan and a more pleasant user experience.

In some examples when fan 124 is operating, fan control instructions 134 determine that the future temperature of the chassis 112 is equal to or above a pre-critical temperature threshold. Based at least on determining that the future temperature of the computing device is equal to or above a pre-critical temperature threshold, fan control instructions 134 increase a first predetermined maximum fan speed to a second predetermined maximum fan speed that is greater than the first predetermined maximum fan speed.

With continued reference to FIG. 3, in one use case example fan 124 is operating at the quiet fan operation profile 152 that includes a first predetermined maximum fan speed 176. Fan control instructions 134 determine that the future temperature of the chassis 112 is equal to or above a pre-critical temperature threshold 178 that represents a temperature that is within a predetermined range of a critical temperature threshold 180, such as equal to or less than 4 degrees from the critical temperature threshold. In one example the pre-critical temperature threshold 178 is 50 degrees C and the critical temperature threshold 180 is 53 degrees C. In the present example, when chassis 112 reaches the critical temperature threshold 180, fan control instructions 134 increase fan speed to a critical speed 182 to provide aggressive cooling of the chassis 112. In some examples the fan speed remains at critical speed 182 until the chassis temperature reaches a critical mode hysteresis temperature 186, at which point fan speed is reduced to the maximum speed associated with the current fan profile configuration.

Based at least on determining that the future temperature of the computing device is equal to or above the pre-critical temperature threshold 178, fan control instructions 134 increase the first predetermined maximum fan speed 176 to a second predetermined maximum fan speed 184 that is greater than the first predetermined maximum fan speed, and in this example represents the maximum fan speed of the performance fan operation profile 156. Advantageously and in this manner, fan control instructions 134 utilize the predicted further temperature of chassis 112 to change the fan profile configuration to the most aggressive profile that provides the highest cooling performance, in this example the performance fan operation profile 156, thereby boosting fan speed to the higher maximum speed associated with the performance fan profile. In this manner, when the predicted temperature approaches the critical chassis temperature 180, fan control instructions 134 preemptively provide additional cooling to the chassis to prevent the actual chassis temperature reaching the critical temperature, and thereby avoid corresponding reductions in performance on the computing device processor(s).

In some examples and with reference again to FIG. 3, after changing the fan profile configuration to the most aggressive profile that provides the highest cooling performance, fan control instructions 134 maintain fan operation at this profile until it is determined that the chassis temperature cools to a reset temperature, in this example the minimum temperature threshold 164, that is less than a maximum speed temperature 188 at which the fan 124 reaches a maximum speed associated with each fan configuration profile. Advantageously, by maintaining the fan operation at the most aggressive profile until it is determined that the chassis temperature has cooled to the reset temperature, fan control instructions 134 increase the likelihood that the thermal event which caused to immediately prior heating of the chassis has ended or will soon end.

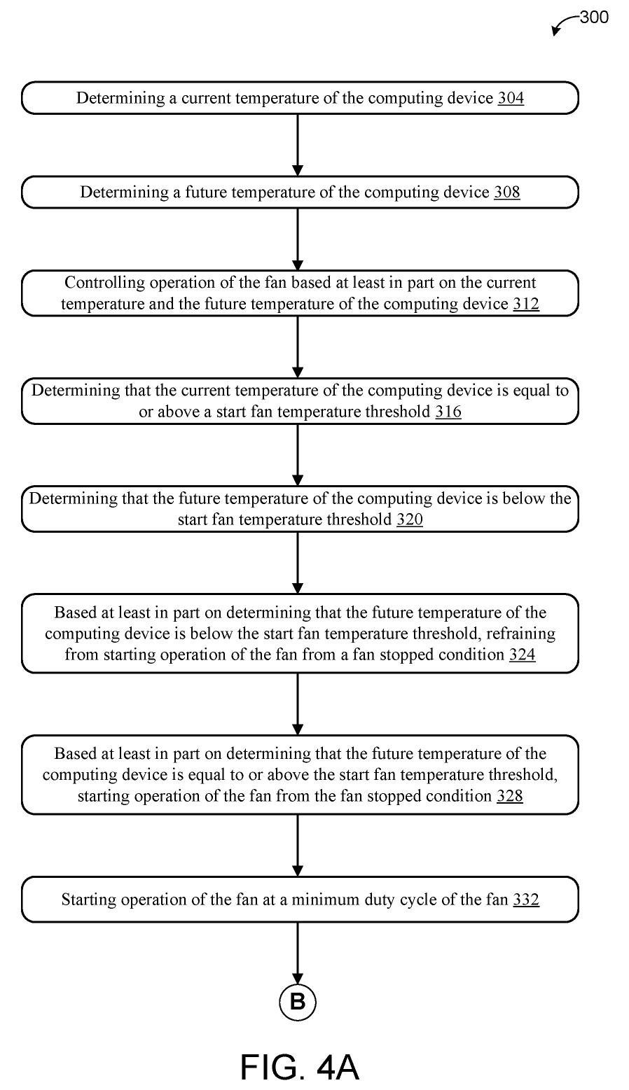

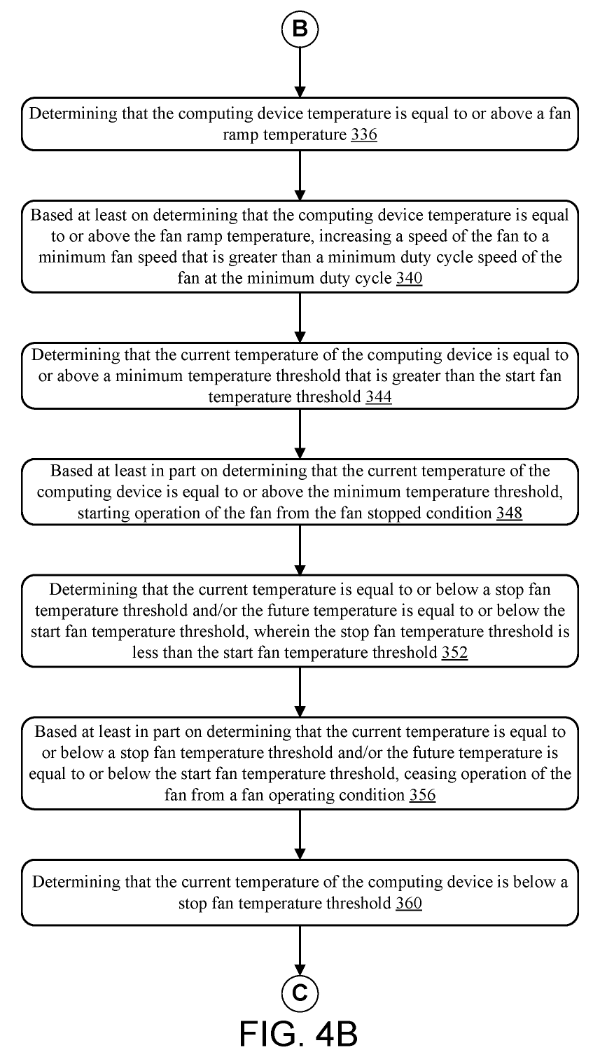

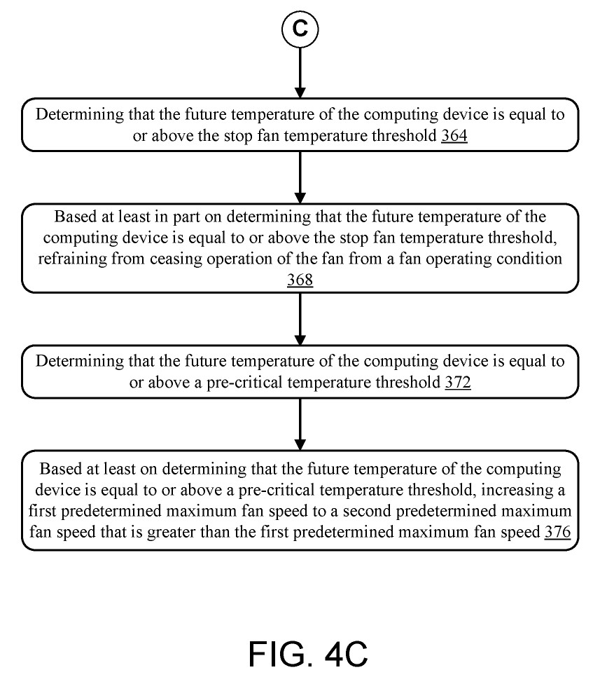

With reference now to FIGS. 4A-4C, an example method 300 of controlling operation of a computing device fan is provided. Method 300 may be implemented using the example configurations of computing device 100 as described above and other configurations as contemplated by the present disclosure. The following description of method 300 is provided with reference to the computing devices and components described herein and shown in FIGS. 1-3 and 5.

It will be appreciated that the following description of method 300 is provided by way of example and is not meant to be limiting. Therefore, it is to be understood that method 300 may include additional and/or alternative steps relative to those illustrated in FIGS. 4A-4C. Further, it is to be understood that the steps of method 300 may be performed in any suitable order. Further still, it is to be understood that one or more steps may be omitted from method 300 without departing from the scope of this disclosure. It will also be appreciated that method 300 also may be performed in other contexts using other suitable components.

With reference now to FIG. 4A, at 304 method 300 includes determining a current temperature of the computing device. At 308 method 300 includes determining a future temperature of the computing device. At 312 method 300 includes controlling operation of the fan based at least in part on the current temperature and the future temperature of the computing device. At 316 method 300 includes, wherein controlling the operation of the fan based at least in part on the current temperature and the future temperature of the computing device comprises determining that the current temperature of the computing device is equal to or above a start fan temperature threshold. At 320 method 300 includes determining that the future temperature of the computing device is below the start fan temperature threshold. At 324 method 300 includes based at least in part on determining that the future temperature of the computing device is below the start fan temperature threshold, refraining from starting operation of the fan from a fan stopped condition.

At 328 method 300 includes, based at least in part on determining that the future temperature of the computing device is equal to or above the start fan temperature threshold, starting operation of the fan from the fan stopped condition. At 332 method 300 includes wherein starting operation of the fan from the fan stopped condition comprises starting operation of the fan at a minimum duty cycle of the fan. With reference now to FIG. 4B, at 336 method 300 includes determining that the computing device temperature is equal to or above a fan ramp temperature. At 340 method 300 includes, based at least on determining that the computing device temperature is equal to or above the fan ramp temperature, increasing a speed of the fan to a minimum fan speed that is greater than a minimum duty cycle speed of the fan at the minimum duty cycle.

At 344 method 300 includes determining that the current temperature of the computing device is equal to or above a minimum temperature threshold that is greater than the start fan temperature threshold. At 348 method 300 includes, based at least in part on determining that the current temperature of the computing device is equal to or above the minimum temperature threshold, starting operation of the fan from the fan stopped condition. At 352 method 300 includes wherein controlling the operation of the fan based at least in part on the current temperature and the future temperature of the computing device comprises determining that the current temperature is equal to or below a stop fan temperature threshold and/or the future temperature is equal to or below the start fan temperature threshold, wherein the stop fan temperature threshold is less than the start fan temperature threshold. At 356 method 300 includes, based at least in part on determining that the current temperature is equal to or below a stop fan temperature threshold and/or the future temperature is equal to or below the start fan temperature threshold, ceasing operation of the fan from a fan operating condition.

At 360 method 300 includes determining that the current temperature of the computing device is below a stop fan temperature threshold. With reference now to FIG. 4C, at 364 method 300 includes determining that the future temperature of the computing device is equal to or above the stop fan temperature threshold. At 368 method 300 includes, based at least in part on determining that the future temperature of the computing device is equal to or above the stop fan temperature threshold, refraining from ceasing operation of the fan from a fan operating condition. At 372 method 300 includes determining that the future temperature of the computing device is equal to or above a pre-critical temperature threshold. At 376 method 300 includes, based at least on determining that the future temperature of the computing device is equal to or above a pre-critical temperature threshold, increasing a first predetermined maximum fan speed to a second predetermined maximum fan speed that is greater than the first predetermined maximum fan speed.

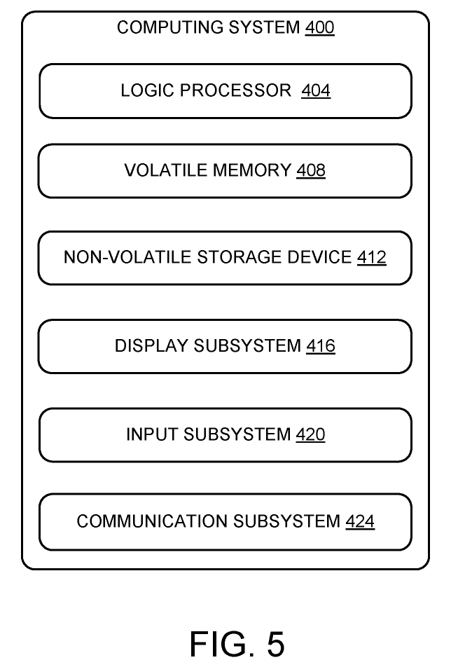

FIG. 5 schematically shows a non-limiting embodiment of a computing system 400 shown in simplified form. Computing system 400 may take the form of one or more computing devices such as personal computers, laptop computers, desktop computers, all-in-one displays, tablet computers, home-entertainment computers, gaming devices or consoles, mobile computing devices, mobile communication devices (e.g., smart phones), head-mounted displays or eyeglasses, and/or other computing devices. In the above examples, computing device 100 may comprise computing system 400 or one or more aspects of computing system 400.

Computing system 400 includes a logic processor 404, volatile memory 408, and a non-volatile storage device 412. Computing system 400 may optionally include a display subsystem 416, input subsystem 420, communication subsystem 424, and/or other components not shown in FIG. 5.

Logic processor 404 includes one or more physical devices configured to execute instructions. For example, the logic processor may be configured to execute instructions that are part of one or more applications, services, programs, routines, libraries, objects, components, data structures, or other logical constructs. Such instructions may be implemented to perform a task, implement a data type, transform the state of one or more components, achieve a technical effect, or otherwise arrive at a desired result.

The logic processor 404 may include one or more physical processors (hardware) configured to execute software instructions. Additionally or alternatively, the logic processor may include one or more hardware logic circuits or firmware devices configured to execute hardware-implemented logic or firmware instructions. Processors of the logic processor 404 may be single-core or multi-core, and the instructions executed thereon may be configured for sequential, parallel, and/or distributed processing. Individual components of the logic processor optionally may be distributed among two or more separate devices, which may be remotely located and/or configured for coordinated processing. Aspects of the logic processor may be virtualized and executed by remotely accessible, networked computing devices configured in a cloud-computing configuration. In such a case, these virtualized aspects are run on different physical logic processors of various different machines, it will be understood.

Volatile memory 408 may include physical devices that include random access memory. Volatile memory 408 is typically utilized by logic processor 404 to temporarily store information during processing of software instructions. It will be appreciated that volatile memory 408 typically does not continue to store instructions when power is cut to the volatile memory 408.

Non-volatile storage device 412 includes one or more physical devices configured to hold instructions executable by the logic processors to implement the methods and processes described herein. When such methods and processes are implemented, the state of non-volatile storage device 412 may be transformed—e.g., to hold different data.

Non-volatile storage device 412 may include physical devices that are removable and/or built-in. Non-volatile storage device 412 may include optical memory (e.g., CD, DVD, HD-DVD, Blu-Ray Disc, etc.), semiconductor memory (e.g., ROM, EPROM, EEPROM, FLASH memory, etc.), and/or magnetic memory (e.g., hard-disk drive, floppy-disk drive, tape drive, MRAM, etc.), or other mass storage device technology. Non-volatile storage device 412 may include nonvolatile, dynamic, static, read/write, read-only, sequential-access, location-addressable, file-addressable, and/or content-addressable devices. It will be appreciated that non-volatile storage device 412 is configured to hold instructions even when power is cut to the non-volatile storage device 412.

Aspects of logic processor 404, volatile memory 408, and non-volatile storage device 412 may be integrated together into one or more hardware-logic components. Such hardware-logic components may include field-programmable gate arrays (FPGAs), program- and application-specific integrated circuits (PASIC / ASICs), program- and application-specific standard products (PSSP / ASSPs), system-on-a-chip (SOC), and complex programmable logic devices (CPLDs), for example.

When included, display subsystem 416 may be used to present a visual representation of data held by non-volatile storage device 412. As the herein described methods and processes change the data held by the non-volatile storage device, and thus transform the state of the non-volatile storage device, the state of display subsystem 416 may likewise be transformed to visually represent changes in the underlying data. Display subsystem 416 may include one or more display devices utilizing virtually any type of technology. Such display devices may be combined with logic processor 404, volatile memory 408, and/or non-volatile storage device 412 in a shared enclosure, or such display devices may be peripheral display devices.

When included, input subsystem 420 may comprise or interface with one or more user-input devices such as an electronic pen, stylus, touchpad, keyboard, mouse, touch screen, or game controller. In some embodiments, the input subsystem may comprise or interface with selected natural user input (NUI) componentry. Such componentry may be integrated or peripheral, and the transduction and/or processing of input actions may be handled on- or off-board. Example NUI componentry may include a microphone for speech and/or voice recognition; an infrared, color, stereoscopic, and/or depth camera for machine vision and/or gesture recognition; a head tracker, eye tracker, accelerometer, and/or gyroscope for motion detection and/or intent recognition; as well as electric-field sensing componentry for assessing brain activity; and/or any other suitable sensor.

When included, communication subsystem 424 may be configured to communicatively couple various computing devices described herein with each other, and with other devices. Communication subsystem 424 may include wired and/or wireless communication devices compatible with one or more different communication protocols. As non-limiting examples, the communication subsystem may be configured for communication via electrostatic voltage antennas, near-field communication (NFC) protocols, wireless telephone network, or a wired or wireless personal-, local- or wide-area network, such as Bluetooth or an HDMI over Wi-Fi connection. In some embodiments, the communication subsystem may allow computing system 400 to send and/or receive messages to and/or from other devices via a network such as the Internet.

The following paragraphs provide additional support for the claims of the application. In one aspect a mobile computing device comprises a chassis; a fan inside the chassis; a temperature sensor; a processor; and a memory storing instructions executable by the processor to: determine a current temperature of the computing device; determine a future temperature of the computing device; and control operation of the fan based at least in part on the current temperature and the future temperature of the computing device. The mobile computing device may additionally or alternatively include, wherein controlling the operation of the fan based at least in part on the current temperature and the future temperature of the computing device comprises: determining that the current temperature of the computing device is equal to or above a start fan temperature threshold; determining that the future temperature of the computing device is below the start fan temperature threshold; and based at least in part on determining that the future temperature of the computing device is below the start fan temperature threshold, refraining from starting operation of the fan from a fan stopped condition. The mobile computing device may additionally or alternatively include, based at least in part on determining that the future temperature of the computing device is equal to or above the start fan temperature threshold, starting operation of the fan from the fan stopped condition. The mobile computing device may additionally or alternatively include, wherein starting operation of the fan from the fan stopped condition comprises starting operation of the fan at a minimum duty cycle of the fan. The mobile computing device may additionally or alternatively include, wherein the instructions are executable to: determine that the computing device temperature is equal to or above a fan ramp temperature; and based at least on determining that the computing device temperature is equal to or above the fan ramp temperature, increase a speed of the fan to a minimum fan speed that is greater than a minimum duty cycle speed of the fan at the minimum duty cycle. The mobile computing device may additionally or alternatively include, wherein the instructions are executable to: determine that the current temperature of the computing device is equal to or above a minimum temperature threshold that is greater than the start fan temperature threshold; and based at least in part on determining that the current temperature of the computing device is equal to or above the minimum temperature threshold, starting operation of the fan from the fan stopped condition. The mobile computing device may additionally or alternatively include, wherein controlling the operation of the fan based at least in part on the current temperature and the future temperature of the computing device comprises: determining that the current temperature is equal to or below a stop fan temperature threshold and/or the future temperature is equal to or below the start fan temperature threshold, wherein the stop fan temperature threshold is less than the start fan temperature threshold; and based at least in part on determining that the current temperature is equal to or below the stop fan temperature threshold and/or the future temperature is equal to or below the start fan temperature threshold, ceasing operation of the fan from a fan operating condition. The mobile computing device may additionally or alternatively include, wherein controlling the operation of the fan based at least in part on the current temperature and the future temperature of the computing device comprises: determining that the current temperature of the computing device is below a stop fan temperature threshold; determining that the future temperature of the computing device is equal to or above the stop fan temperature threshold; and based at least in part on determining that the future temperature of the computing device is equal to or above the stop fan temperature threshold, refraining from ceasing operation of the fan from a fan operating condition. The mobile computing device may additionally or alternatively include, wherein the instructions are executable to: determine that the future temperature of the computing device is equal to or above a pre-critical temperature threshold; and based at least on determining that the future temperature of the computing device is equal to or above a pre-critical temperature threshold, increase a first predetermined maximum fan speed to a second predetermined maximum fan speed that is greater than the first predetermined maximum fan speed. The mobile computing device may additionally or alternatively include, wherein the temperature of the computing device comprises a temperature of the chassis.

Another aspect provides, in a computing device comprising a fan and a chassis, a method of controlling operation of the fan, the method comprising: determining a current temperature of the computing device; determining a future temperature of the computing device; and controlling operation of the fan based at least in part on the current temperature and the future temperature of the computing device. The method may additionally or alternatively include, wherein controlling the operation of the fan based at least in part on the current temperature and the future temperature of the computing device comprises: determining that the current temperature of the computing device is equal to or above a start fan temperature threshold; determining that the future temperature of the computing device is below the start fan temperature threshold; and based at least in part on determining that the future temperature of the computing device is below the start fan temperature threshold, refraining from starting operation of the fan from a fan stopped condition. The method may additionally or alternatively include, based at least in part on determining that the future temperature of the computing device is equal to or above the start fan temperature threshold, starting operation of the fan from the fan stopped condition. The method may additionally or alternatively include, wherein starting operation of the fan from the fan stopped condition comprises starting operation of the fan at a minimum duty cycle of the fan. The method may additionally or alternatively include, determining that the computing device temperature is equal to or above a fan ramp temperature; and based at least on determining that the computing device temperature is equal to or above the fan ramp temperature, increasing a speed of the fan to a minimum fan speed that is greater than a minimum duty cycle speed of the fan at the minimum duty cycle. The method may additionally or alternatively include determining that the current temperature of the computing device is equal to or above a minimum temperature threshold that is greater than the start fan temperature threshold; and based at least in part on determining that the current temperature of the computing device is equal to or above the minimum temperature threshold, starting operation of the fan from the fan stopped condition. The method may additionally or alternatively include, wherein controlling the operation of the fan based at least in part on the current temperature and the future temperature of the computing device comprises: determining that the current temperature is equal to or below a stop fan temperature threshold and/or the future temperature is equal to or below the start fan temperature threshold, wherein the stop fan temperature threshold is less than the start fan temperature threshold; and based at least in part on determining that the current temperature is equal to or below a stop fan temperature threshold and/or the future temperature is equal to or below the start fan temperature threshold, ceasing operation of the fan from a fan operating condition. The method may additionally or alternatively include, wherein controlling the operation of the fan based at least in part on the current temperature and the future temperature of the computing device comprises: determining that the current temperature of the computing device is below a stop fan temperature threshold; determining that the future temperature of the computing device is equal to or above the stop fan temperature threshold; and based at least in part on determining that the future temperature of the computing device is equal to or above the stop fan temperature threshold, refraining from ceasing operation of the fan from a fan operating condition. The method may additionally or alternatively include determining that the future temperature of the computing device is equal to or above a pre-critical temperature threshold; and based at least on determining that the future temperature of the computing device is equal to or above a pre-critical temperature threshold, increasing a first predetermined maximum fan speed to a second predetermined maximum fan speed that is greater than the first predetermined maximum fan speed.

Another aspect provides a mobile computing device comprising: a chassis; a fan inside the chassis; a temperature sensor; a processor; and a memory storing instructions executable by the processor to: determine a current temperature of the chassis; determine a future temperature of the chassis; determine that the current temperature of the chassis is equal to or above a start fan temperature threshold; determine that the future temperature of the chassis is below the start fan temperature threshold; and based at least in part on determining that the future temperature of the chassis is below the start fan temperature threshold, refraining from starting operation of the fan from a fan stopped condition.

It will be understood that the configurations and/or approaches described herein are exemplary in nature, and that these specific embodiments or examples are not to be considered in a limiting sense, because numerous variations are possible.

The subject matter of the present disclosure includes all novel and non-obvious combinations and sub-combinations of the various processes, systems and configurations, and other features, functions, acts, and/or properties disclosed herein, as well as any and all equivalents thereof.

The claims may refer to “an” element or “a first” element or the equivalent thereof. Such claims should be understood to include incorporation of one or more such elements, neither requiring nor excluding two or more such elements. Other combinations and sub-combinations of the disclosed features, functions, elements, and/or properties may be claimed through amendment of the present claims or through presentation of new claims in this or a related application. Such claims, whether broader, narrower, equal, or different in scope to the original claims, also are regarded as included within the subject matter of the present disclosure. As used herein, the phrase “and/or” means any or all of multiple stated possibilities.

1. A mobile computing device comprising:
a chassis;
a fan inside the chassis;
a temperature sensor;
a processor; and
a memory storing instructions executable by the processor to:
determine a current temperature of the computing device;
determine a future temperature of the computing device; and
control operation of the fan based at least in part on the current temperature and the future temperature of the computing device.

2. The mobile computing device of claim 1, wherein controlling the operation of the fan based at least in part on the current temperature and the future temperature of the computing device comprises:
determining that the current temperature of the computing device is equal to or above a start fan temperature threshold;
determining that the future temperature of the computing device is below the start fan temperature threshold; and
based at least in part on determining that the future temperature of the computing device is below the start fan temperature threshold, refraining from starting operation of the fan from a fan stopped condition.

3. The mobile computing device of claim 2, further comprising, based at least in part on determining that the future temperature of the computing device is equal to or above the start fan temperature threshold, starting operation of the fan from the fan stopped condition.

4. The mobile computing device of claim 3, wherein starting operation of the fan from the fan stopped condition comprises starting operation of the fan at a minimum duty cycle of the fan.

5. The mobile computing device of claim 4, wherein the instructions are executable to:
determine that the computing device temperature is equal to or above a fan ramp temperature; and
based at least on determining that the computing device temperature is equal to or above the fan ramp temperature, increase a speed of the fan to a minimum fan speed that is greater than a minimum duty cycle speed of the fan at the minimum duty cycle.

6. The mobile computing device of claim 2, wherein the instructions are executable to:
determine that the current temperature of the computing device is equal to or above a minimum temperature threshold that is greater than the start fan temperature threshold; and
based at least in part on determining that the current temperature of the computing device is equal to or above the minimum temperature threshold, starting operation of the fan from the fan stopped condition.

7. The mobile computing device of claim 2, wherein controlling the operation of the fan based at least in part on the current temperature and the future temperature of the computing device comprises:
determining that the current temperature is equal to or below a stop fan temperature threshold and/or the future temperature is equal to or below the start fan temperature threshold, wherein the stop fan temperature threshold is less than the start fan temperature threshold; and
based at least in part on determining that the current temperature is equal to or below the stop fan temperature threshold and/or the future temperature is equal to or below the start fan temperature threshold, ceasing operation of the fan from a fan operating condition.

8. The mobile computing device of claim 1, wherein controlling the operation of the fan based at least in part on the current temperature and the future temperature of the computing device comprises:
determining that the current temperature of the computing device is below a stop fan temperature threshold;
determining that the future temperature of the computing device is equal to or above the stop fan temperature threshold; and
based at least in part on determining that the future temperature of the computing device is equal to or above the stop fan temperature threshold, refraining from ceasing operation of the fan from a fan operating condition.

9. The mobile computing device of claim 1, wherein the instructions are executable to:
determine that the future temperature of the computing device is equal to or above a pre-critical temperature threshold; and
based at least on determining that the future temperature of the computing device is equal to or above a pre-critical temperature threshold, increase a first predetermined maximum fan speed to a second predetermined maximum fan speed that is greater than the first predetermined maximum fan speed.

10. The mobile computing device of claim 1, wherein the temperature of the computing device comprises a temperature of the chassis.

11. In a computing device comprising a fan and a chassis, a method of controlling operation of the fan, the method comprising:
determining a current temperature of the computing device;
determining a future temperature of the computing device; and
controlling operation of the fan based at least in part on the current temperature and the future temperature of the computing device.

12. The method of claim 11, wherein controlling the operation of the fan based at least in part on the current temperature and the future temperature of the computing device comprises:
determining that the current temperature of the computing device is equal to or above a start fan temperature threshold;
determining that the future temperature of the computing device is below the start fan temperature threshold; and
based at least in part on determining that the future temperature of the computing device is below the start fan temperature threshold, refraining from starting operation of the fan from a fan stopped condition.

13. The method of claim 12, further comprising, based at least in part on determining that the future temperature of the computing device is equal to or above the start fan temperature threshold, starting operation of the fan from the fan stopped condition.

14. The method of claim 13, wherein starting operation of the fan from the fan stopped condition comprises starting operation of the fan at a minimum duty cycle of the fan.

15. The method of claim 14, further comprising:
determining that the computing device temperature is equal to or above a fan ramp temperature; and
based at least on determining that the computing device temperature is equal to or above the fan ramp temperature, increasing a speed of the fan to a minimum fan speed that is greater than a minimum duty cycle speed of the fan at the minimum duty cycle.

16. The method of claim 12, further comprising:
determining that the current temperature of the computing device is equal to or above a minimum temperature threshold that is greater than the start fan temperature threshold; and
based at least in part on determining that the current temperature of the computing device is equal to or above the minimum temperature threshold, starting operation of the fan from the fan stopped condition.

17. The method of claim 12, wherein controlling the operation of the fan based at least in part on the current temperature and the future temperature of the computing device comprises:
determining that the current temperature is equal to or below a stop fan temperature threshold and/or the future temperature is equal to or below the start fan temperature threshold, wherein the stop fan temperature threshold is less than the start fan temperature threshold; and
based at least in part on determining that the current temperature is equal to or below a stop fan temperature threshold and/or the future temperature is equal to or below the start fan temperature threshold, ceasing operation of the fan from a fan operating condition.

18. The method of claim 11, wherein controlling the operation of the fan based at least in part on the current temperature and the future temperature of the computing device comprises:
determining that the current temperature of the computing device is below a stop fan temperature threshold;
determining that the future temperature of the computing device is equal to or above the stop fan temperature threshold; and
based at least in part on determining that the future temperature of the computing device is equal to or above the stop fan temperature threshold, refraining from ceasing operation of the fan from a fan operating condition.

19. The method of claim 11, further comprising:
determining that the future temperature of the computing device is equal to or above a pre-critical temperature threshold; and
based at least on determining that the future temperature of the computing device is equal to or above a pre-critical temperature threshold, increasing a first predetermined maximum fan speed to a second predetermined maximum fan speed that is greater than the first predetermined maximum fan speed.

20. A mobile computing device comprising:
a chassis;
a fan inside the chassis;
a temperature sensor;
a processor; and
a memory storing instructions executable by the processor to:
determine a current temperature of the chassis;
determine a future temperature of the chassis;
determine that the current temperature of the chassis is equal to or above a start fan temperature threshold;
determine that the future temperature of the chassis is below the start fan temperature threshold; and
based at least in part on determining that the future temperature of the chassis is below the start fan temperature threshold, refraining from starting operation of the fan from a fan stopped condition.
